(19) United States
(12) Patent Application Publication
(10) Pub. No.: US 2008/0259576 A1
(43) Pub. Date: Oct. 23, 2008

(54) Electronic Device or Circuit and Method for Fabricating the Same

(75) Inventors: Mark Thomas Johnson, Veldhoven (NL); Adrianus Sempel, Waarle (NL); Franciscus Petrus Widdershoven, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/089,255

(22) PCT Filed: Sep. 29, 2006
(86) PCT No.: PCT/IB2006/053572

§ 371 Date: Apr. 4, 2008

(30) Foreign Application Priority Data
Oct. 13, 2005 (EP) 05109504.0

(51) Int. Cl. H01L 21/58; H05K 1/00

(52) U.S. Cl. 361/749; 438/125; 257/E21.505

(57) ABSTRACT

A method for fabricating an electronic device or circuit, respectively, comprises providing a flexible substrate (1), defining onto the flexible substrate (1) electric components (2, 3, 3′, 3″, 3′″, 7, 11, 12) and interconnects (8), introducing out breaks (4, 4′, 4″, 4a-4s) in the flexible substrate (1) between the electric components and/or interconnects, and forming the flexible substrate (1) into a deformed configuration by deforming, particularly folding, parts of the flexible substrate as determined by the breaks (4, 4′, 4″, 4a-4s).

The invention relates to a method for fabricating an electronic device or circuit, respectively, comprising providing a flexible substrate, and defining onto the flexible substrate electric components and interconnects.

The invention further relates to an electronic device or circuit, respectively, comprising a flexible substrate, onto which electric components and interconnects are defined.

In many cases, the cost of an electronic device or circuit scales linearly with the area of the substrate on which it is manufactured. For this reason, many products benefit from component miniaturization and the efficient packing of e.g. components onto printed circuit boards (PCBs) to realize cost reductions. However, it should be noted that miniaturization of components and efficient packing of these components requires the use of expensive multi-layer PCBs and application of multi-layer fabrication techniques. On the other hand, there are several classes of products where the physical size of the product must exceed the minimum size required to house the necessary electronics, wiring, interconnect etc. Such products can be grouped into products where:

a larger size is required for physical reasons (e.g. to increase the sensitivity of an input device or increase the performance of an output device). Such devices include sensors, loudspeakers, antennas for RFID tags etc.;

a larger size is required for “human compatibility reasons”. Such devices include displays, keyboards, headphones etc.

The problem with these types of electronics applications is that the cost of the device (which generally scales as a linear function of the device area) will remain high and become a dominant factor in the cost price of a product.

It is an object of the invention to provide a method of the type defined in the opening paragraph and a device or circuit of the type defined in the second paragraph, in which the disadvantages defined above are avoided.

In order to achieve the object defined above, with a method according to the invention characteristic features are provided so that a method according to the invention can be characterized in the way defined below, that is:

A method for fabricating an electronic device or circuit, respectively, comprising providing a flexible substrate, defining onto the flexible substrate electric components and optionally interconnects, introducing breaks in the flexible substrate between the electric components and/or interconnects, and forming the flexible substrate into a deformed configuration by deforming parts of the flexible substrate as determined by the breaks.

In order to achieve the object defined above, with an electronic device or circuit, respectively, characteristic features are provided so that an electronic device or circuit according to the invention can be characterized in the way defined below, that is:

An electronic device or circuit, respectively, comprising a flexible substrate, onto which electric components and optionally interconnects are defined, wherein in the flexible substrate between the electric components and/or interconnects breaks are introduced, so that the flexible substrate is deformable or has a deformed configuration, respectively, as determined by the breaks.

In order to achieve the object defined above, an electronic device or circuit, respectively, comprising a flexible substrate, onto which electric components and optionally interconnects are defined, wherein the flexible substrate has a deformed configuration, is obtainable by a fabricating method according to the present invention.

The characteristic features according to the invention provide the advantage that electronic devices and circuits, like integrated electronics systems or passive electronic components, are created that are distributed over a far larger area than that of the actual substrate upon which they are manufactured. The invention is particularly applicable to distributed electronics systems with built-in interconnects for input applications, like sensors and sensor-arrays, output applications, like displays and loudspeakers, passive components and power distribution systems that are distributed over a far larger area than the actual substrate upon which they are manufactured. The present invention is generally aimed at applications that need to show a conformable or rollable configuration, e.g. flexible displays, but also any wearable electronics and specifically sensors for attaching to the human or animal body.

It should be mentioned that the term “electric components” as used herein comprises active electronic components, like semiconductors, and passive components, like resistors, capacitors and inductors.

It may be mentioned that document US 2004/0115866 A1 discloses a process for fabricating a microelectronic package, wherein a substrate is folded by engaging a folding portion of the substrate with a die so that the folding portion pivots with respect to a first portion of the substrate. However, this document does not address the problem of the present invention, nor does it give any hints to the present solution. Rather, it is aimed at providing accurate folding in order to minimize the size of the resulting microelectronic package. Particularly, US 2004/0115866 A1 does not reveal a concept of introducing breaks into a substrate followed by deforming (extending) the substrate together with electric circuitry positioned thereon, but simply explains how to fold a substrate across a former element.

According to one embodiment of the invention the flexible substrate in its deformed configuration is attached to a carrier substrate. This provides the advantage that the deformed configuration is kept in a stable state by the carrier substrate, thereby protecting the flexible substrate from being stretched or torn. An even better protection of the electronic device or circuit is achieved, if the deformed configuration of the flexible substrate is sandwiched between the carrier substrate and a cover substrate. It should be noted that the carrier substrate and the cover substrate consist of materials, like a plastic film, paper, etc., that are much cheaper than the flexible substrate. In a preferred embodiment, the thickness and the mechanical properties of the carrier substrate and the cover substrate are substantially the same.

In order to maximize the area of distribution of the electric components or the mutual distance of electronic components, while still keeping the actual size of area of the flexible substrate, small parts of the flexible substrate are folded in such a manner that electronic components are extended.

In order to implement a multi-layer configuration of the electronic device or circuit without the need for using multi-layer PCBs or applying multi-layer fabrication processes in a further embodiment of the invention the flexible substrate is folded into a multi-layer configuration.

In order to minimize electromagnetic radiation emitted by the interconnect wires and noise picked-up by the interconnect wires, it is advantageous to fold parts of the flexible substrate containing interconnects into a twisted configuration.

In order to make sure that deforming, particularly folding, the flexible substrate does not result in fracture of the interconnect, interconnects at the deforming parts, particularly at folding parts, of the flexible substrate may be defined as a plurality of split conducting lines.

By defining LTPS (Low Temperature Poly-Silicon) based electronic components on the flexible substrate production costs can be kept low, while on the other hand, these components are applicable to high-frequency circuits. LTPS technology per se is well known among those skilled in the art and the design rules for LTPS are well established. LTPS provides the advantage that electronic components, like transistors, can be provided directly on a foil that is sufficiently high temperature compatible, e.g. that stands about 200° C. Alternatively, the electronic components can be arranged on a foil by use of transfer techniques (SUrface Free Technology by Laser Annealing/ablation [SUFTLA], etc.). According to the specific application it is possible to make a complete control IC into the LTPS. Further it is possible to provide electrostatic discharge (ESD) protection in LTPS.

According to the invention the electric components may also comprise amorphous silicon based electronic components, nano-crystalline silicon based electronic components, micro-crystalline silicon based electronic components, hydrogenated a-Si nitride based electronic components, CdSe based electronic components, polymer based electronic components, or silicon-on-insulator/silicon-on-anything, CMOS, BiPolar CMOS, GaAs, SiGe based electronic components.

The aspects defined above and further aspects of the invention are apparent from exemplary embodiments to be described hereinafter and are explained with reference to these exemplary embodiments.

The invention will be described in more detail hereinafter with reference to exemplary embodiments. However, the invention is not limited to these exemplary embodiments.

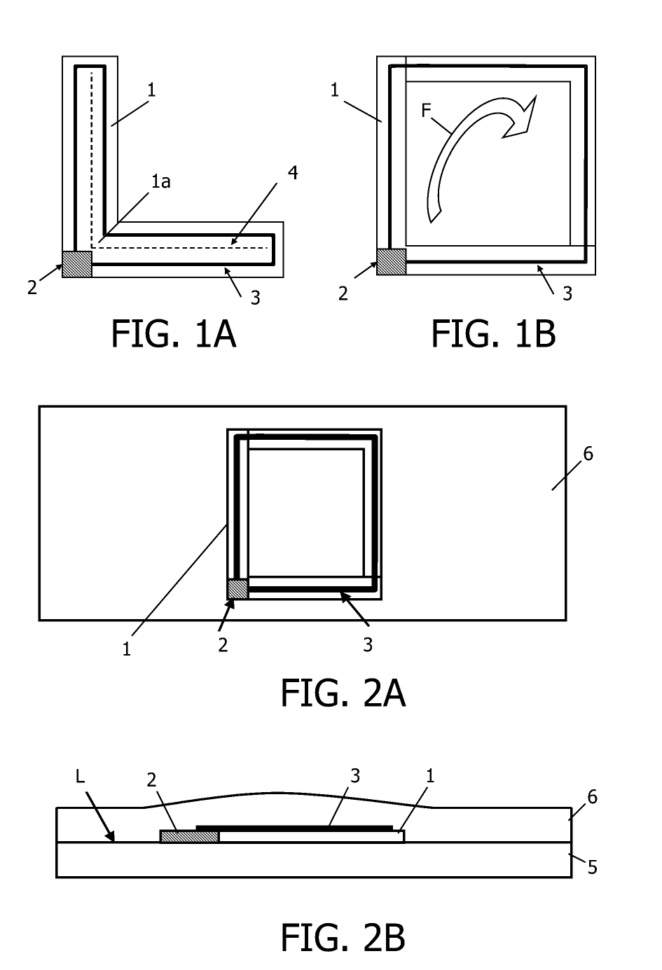

FIG. 1A and FIG. 1B show a first embodiment of the method according to the invention for fabricating an electronic device in form of an RFID tag.

FIGS. 2A and 2B show in top view and cross section, respectively, the RFID tag according to the first embodiment, sandwiched between two protective substrates.

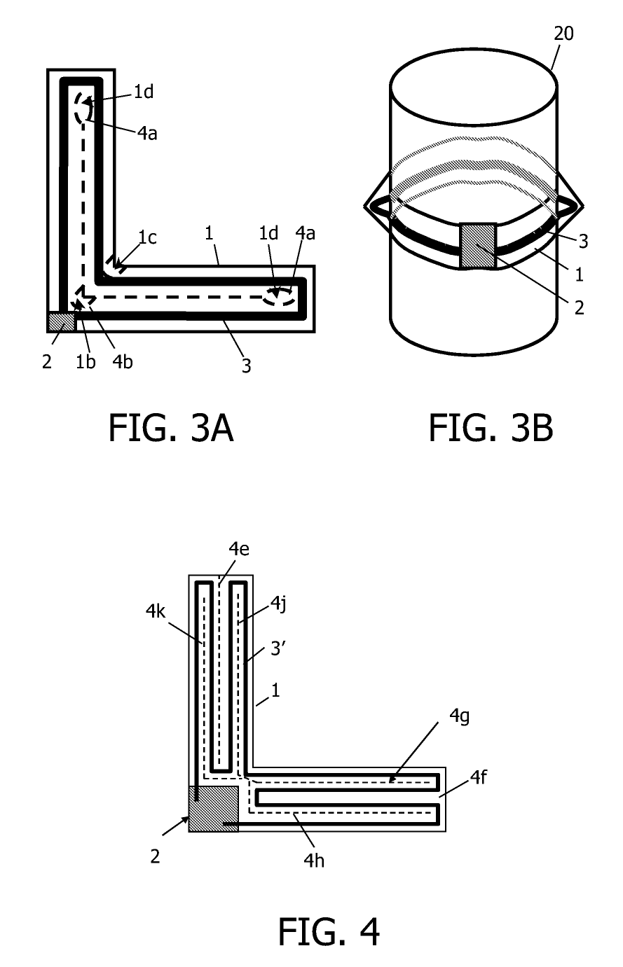

FIG. 3A and FIG. 3B show a variation on the first embodiment of the invention in top view and perspective view, respectively.

FIG. 4 shows another embodiment of the invention in top view.

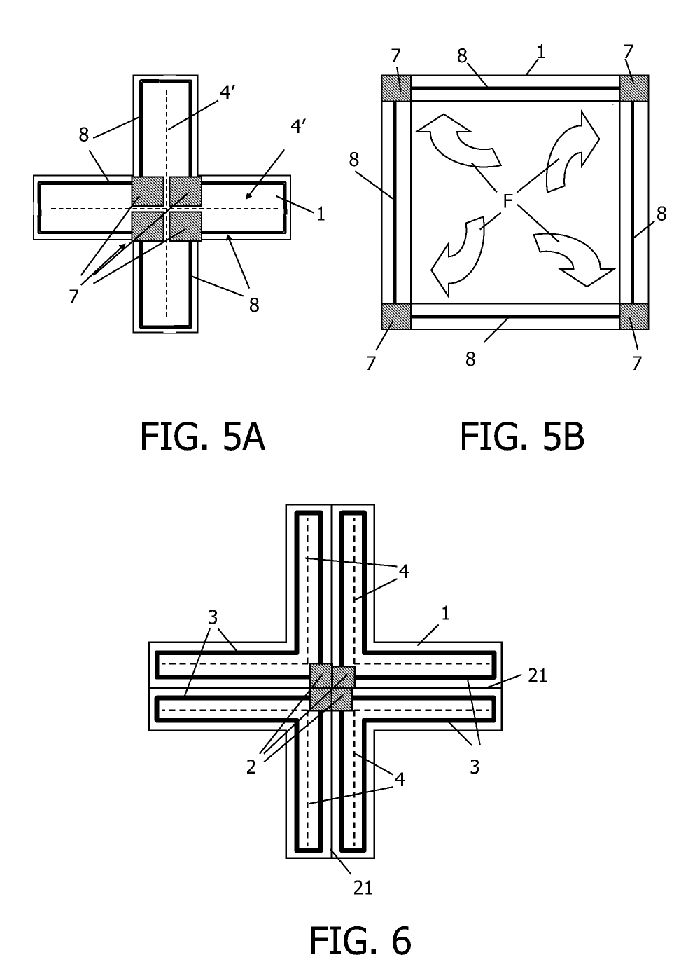

FIG. 5A and FIG. 5B show another embodiment of the invention in top view.

FIG. 6 shows another embodiment of the invention in top view.

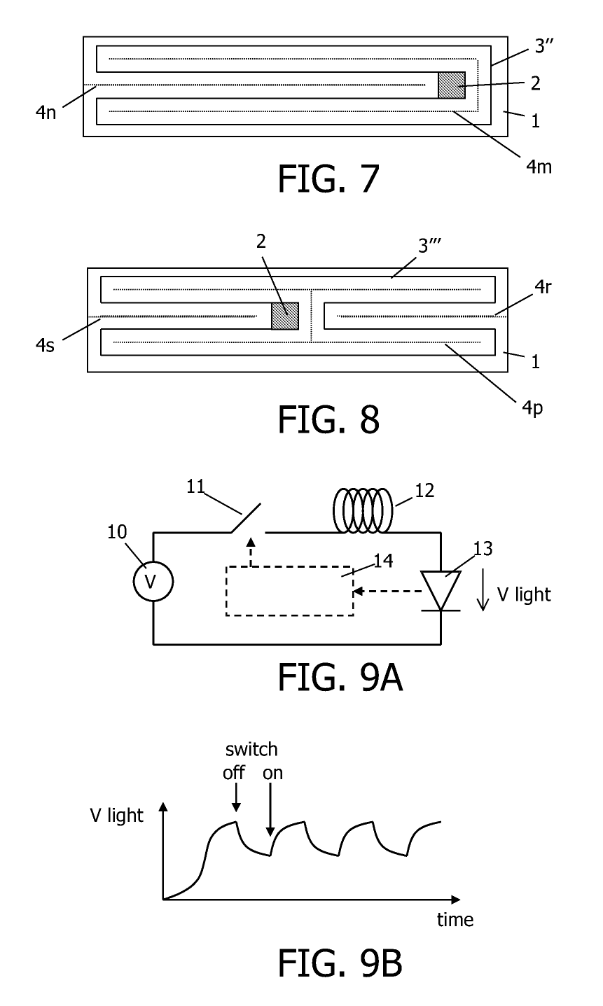

FIG. 7 shows another embodiment of the invention in top view.

FIG. 8 shows another embodiment of the invention in top view.

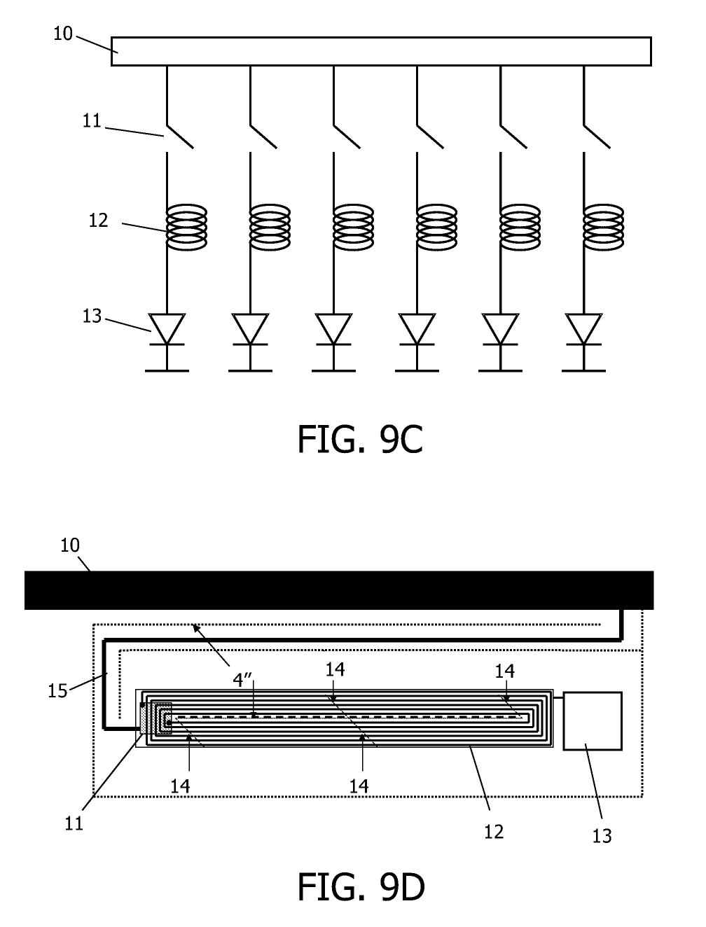

FIG. 9A shows a basic circuit diagram of an electronic circuit manufactured according to the invention.

FIG. 9B shows a timing diagram for the electronic circuit according to FIG. 9A.

FIG. 9C shows an electronic circuit that comprises a plurality of electronic circuits according to FIG. 9A.

FIG. 9D shows a top view of a layout of the electronic circuit according to FIG. 9A on a flexible substrate according to the invention.

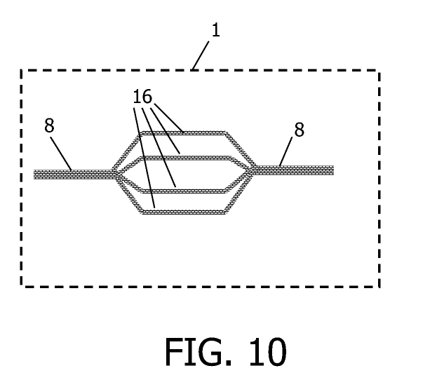

FIG. 10 shows a top view of a layout of an interconnect according to the invention.

The present invention is now explained with the help of various embodiments enlightening the creation of electronic devices or circuits, like integrated electronics systems or passive electronic components, that are distributed over a far larger area than the actual substrate upon which they are manufactured. In this manner, the device sensitivity is increased whilst the cost price remains low. The electronic devices and circuits are realized in a flexible substrate based electronics technology, such as low temperature poly-Si (LTPS), making use of a cut-fold-extend approach. It is well known that LTPS can be realized on flexible substrates either by directly fabricating the LTPS onto a plastic or metal foil substrate, or alternatively by transferring the LTPS from a (glass) substrate on which it is manufactured onto a flexible substrate. Using this technology, the inventors propose to create distributed electronics systems with built-in interconnect for input (sensors) and output (display, loudspeaker) applications. In addition, it is proposed to create passive components and power distribution systems that are distributed over a far larger area than the actual substrate upon which they are manufactured by using a cut-fold-extend approach.

FIG. 1A and FIG. 1B show the method for fabricating an electronic device according to the invention, wherein the electronic device is incorporated as an RFID tag. The RFID tag comprises a single flexible substrate 1, onto which a driving electronics component 2 and a passive antenna 3 are defined. The RFID tag is based on LTPS technology. FIG. 1A shows the layout on the flexible LTPS substrate 1 using minimum substrate area. As will be appreciated the electronic driving component 2 and the integrated antenna 3 are realized in a close packed LTPS layout on the flexible substrate 1. In this manner, the necessary amount of LTPS substrate, and hence the costs, are minimized.

The antenna 3 is made in the form of a meandering structure. Next, a right-angled cut 4 is carried out through the flexible substrate 1 between the meanders of the antenna 3. The required cutting steps can be realized by e.g. laser cutting or other known manufacturing methods such as stamping with a sharp blade etc. It should be observed that the layout of the RFID tag can be separated from the remainder of the flexible substrate 1, before or after the cut 4 has been carried out.

Next, according to the invention the RFID tag is formed into a folded configuration such that the antenna 3 is in an extended state. This is achieved by folding a part of the substrate 1 including a corner 1a as determined by cut 4, whereby a large and sensitive antenna 3 is realized. This folding step is illustrated in FIG. 1B. Alternatively, the extension could be achieved by deforming the antenna into a rounded form, without introducing a sharp fold, as explained in the following with reference to FIGS. 3A and 3B.

FIG. 3A and FIG. 3B show a variation on the first embodiment of the invention in top view and perspective view, respectively. In this embodiment the cut 4 terminates in closed loops 4a, 4a surrounding portions 1d, 1d of the flexible substrate 1, which portions 1d, 1d are removed from the flexible substrate 1 due to the closed loop configuration of the cut, leaving recesses in the flexible substrate 1. Another portion 1b of the flexible substrate 1 is removed by carrying out another cut 4b. Finally, a fourth portion 1c is punched at the corner of the flexible substrate adjacent to the driving electronics component 2. Due to removing the portions 1a, 1a, 1b, 1c of the flexible substrate 1 the present electronic device can be deformed into a rounded shape without introducing sharp folds, as depicted in FIG. 3B, where the electronic device in its rolled-out configuration has been put around a transparent cylindrical body 20. The grey lines display the portion of the electronic device at the back side of the cylindrical body 20.

FIG. 4 shows another embodiment of the invention in top view. This embodiment differs from the first embodiment of the invention in that it has a multiply meandered structure of the electronic component 3′, which may be configured as an antenna of an RFID tag. The turns of the meandered electronic component 3′ are separated from each other by alternately introducing central breaks 4g, 4h, 4j, 4k that do not extend to a peripheral edge of the flexible substrate 1 and peripheral breaks 4e, 4f that extend to peripheral edges of the flexible substrate 1. Due to the multiple meanders the electronic component 3′ can be expanded into an even larger effective size which e.g. yields an antenna of considerably increased sensitivity.

Whilst the above examples are related to integrated tags, comprising both driving electronics and passive antenna on a single substrate, there are many more applications for the “cut-fold-extend” concept for creating (integrated) electronics which is distributed over a far larger area than the actual substrate upon which it is manufactured.

In this respect, the “cut-fold-extend” technology could be viewed as a replacement for the traditional printed circuit board (“PCB”) technology in applications where it is necessary or desirable that space is created between the electronic components.

FIGS. 2A and 2B show in top view and cross section, respectively, the RFID tag sandwiched between two protective substrates, in order to protect the deformed configuration of the flexible substrate 1. The RFID tag is attached to a (cheaper) carrier substrate 5 which can consist of a plastic film, smart card, paper or the like. Alternatively, carrier substrate 5 can form part of a product or surface onto which the RFID tag is directly stuck. Next, a cover substrate 6 is applied onto the carrier substrate 5 and the RFID tag. Thereby, the RFID tag is in a sandwiched configuration sealed between the carrier substrate 5 and the cover substrate 6, which, for example, are thin plastic films that are laminated together (arrow L). Preferably, the carrier substrate 5 and the cover substrate 6 have the same thickness and mechanical properties such as elasticity constants, whereby the bending stress on the RFID tag is minimized.

Alternatively, the RFID tag is first cut out, before being locally attached to the carrier substrate 5 (e.g. at the position of the driving electronics component 2). The antenna 3 could then be folded out with the RFID tag in contact with the carrier substrate 5, and held in place by the sealing step with the cover substrate 6.

It is apparent that as the proposed manufacturing process requires a flexible substrate 1, devices made using the cut-fold-extend approach will be intrinsically suitable for security paper applications, such as banknotes, passports, travel cheques etc.

The resulting RFID tag sealed in a package would be supplied to the manufacturer of the security paper to be incorporated into the paper (e.g. by weaving it into the paper).

FIG. 5A and FIG. 5B show another embodiment of the invention in top view. This embodiment comprises the fabrication of distributed electronic modules 7 with integrated interconnects 8. In this embodiment, again the inventive concept of defining both electronics modules 7 and interconnects 8 (wiring) in a compact manner on a flexible substrate 1 is applied, but in this case it is the goal of distributing many (in this example four) small electronics modules 7 across a large area to create a connected system without having to later interconnect all the electronic modules 7 together. After the electronic modules 7 and the interconnects 8 have been defined on the flexible substrate 1, two cuts 4′ are carried out crosswise so that they separate the electronic modules 7 from each other and extend between meanders of the interconnects 8. The cuts 4′ determine parts of the flexible substrate 1 that are subsequently folded out into an extended folded configuration, as depicted by the arrows F, wherein the electronic modules 7 are distributed over a wide area. In this manner, it is, for instance, possible to realize a large size active matrix display, but also many other applications can be realized, such as:

Input devices: Sensor arrays, such as optical or capacitive (fingerprint) sensors, or other touch sensors for use in e.g. input devices such as keyboards or touch pads etc. One of the advantages of locally creating electronics is that it is easier to create matched transistors (as process variations are statistically smaller over small areas). Matched transistors, as used herein, particularly means matching in respect of mobility and threshold voltage. By later cutting, folding and extending, the matched transistors are later distributed across a large area, giving the possibilities of realizing matched transistors with any desired separation. This is particularly attractive for realizing highly uniform sensors.

Output devices: In addition to displays also loudspeaker arrays where a series of (electrostatic) loudspeakers are driven with related amplitudes and phases to e.g. direct sound or create surround sound impressions.

FIG. 6 shows another embodiment of the invention that is similar to that depicted in FIG. 5A and FIG. 5B. The electronic device of FIG. 6 comprises four electronic components 2, e.g. RFID tag electronics, and four individual antennas 3. The antennas 3 can be expanded after four breaks 4 have been introduced into the flexible substrate 1. The electronic device of FIG. 6 can be separated into four independent devices by cutting along the separation lines 21, 21. However, it should be noted that instead of providing four electronic components 2 one single electronic component 2 with four independent antennas 3 can be arranged on the flexible substrate 1, in which case the separation lines 21 are omitted. In the latter situation, it would also be possible to replace the four electronic components 2 with just a single electronic component associated with all four antennas 3.

The embodiments of the invention explained so far have either an L-shaped or cross-shaped configuration of the flexible substrate 1 before expanding. However, this may result in an inefficient use of the flexible substrate 1 as it is difficult to layout electronic devices adjacent to each other without introducing dead areas between these devices. Therefore, in preferred embodiments of the invention layouts of the electronic devices are proposed that are essentially in a simple rectangular form. This makes it easier to put them on a wafer or substrate in a regular X-Y pattern and increases the usage efficiency of the flexible substrate 1. FIGS. 7 and 8 show in top view two examples of electronic devices with rectangular layouts on a flexible substrate 1.

The electronic device of FIG. 7 comprises an electronic component 2 to which another electronic component in form of an antenna 3″ is attached. The antenna 3″ comprises a meandering structure. Turns of the meandering antenna 3″ are separated from each other by a U-shaped central break 4m in the flexible substrate 1 and by a peripheral break 4n, respectively, which peripheral break 4n extends from a peripheral edge of the flexible substrate 1 into a region between the legs of the U-shaped central break 4m.

The electronic device of FIG. 8 comprises an electronic component 2 to which another electronic component in form of an meandering antenna 3′″ is attached. Turns of the meandering antenna 3′″ are separated from each other by an H-shaped central break 4p in the flexible substrate 1 and by straight peripheral breaks 4r, 4s, respectively, which peripheral break 4r, 4s extend from opposite peripheral edges of the flexible substrate 1 between legs of the H-shaped central break 4p.

Now another embodiment of the invention is explained, containing discrete passive and active electric components. Also in this embodiment it is the goal to define the discrete devices on a flexible substrate and then cut, fold and extend the flexible substrate as described above to create a larger effective device. Again, the cost saving is in the area of substrate required for the passive components. If necessary, these discrete components can be combined with other electronics modules, for example CMOS or LTPS etc. to form matrices of devices for distributed applications.

The following devices have been considered:

Inductors, as these are essentially electrical windings, similar to antennas

Magnetic sensors (also containing windings)

Transformers for AC/AC conversion (in this case coupled windings), which could form a part of a switched mode power supply.

The aforesaid components benefit from the increased size of the windings made available using the cut-fold-extend approach as this results in an increase of their performance (higher inductance value, higher sensitivity magnetic sensor, higher efficiency and higher power level transformer) without an increase in substrate area and hence price.

FIG. 9A shows an exemplary basic circuit diagram of an electronic circuit for converting high voltage power to local low voltage for driving an LED light source. This electronic circuit comprises the above mentioned inductors in the form of switchable windings, power electronics and the like. In detail, this electronic circuit comprises a high voltage distributed power supply 10 (which may be mains AC voltage, or high voltage DC rectified voltage), which high voltage is converted to a lower voltage Vlight by a switching power transistor 11 and an inductor 12, see the timing diagram in FIG. 9B. The circuit ensures that the lower voltage Vlight fed to an LED 13 remains low, whilst the brightness of the LED 13 is controlled by the duty cycle of the power transistor switch 11. Optionally, an optical feedback 14 can be introduced to compensate for aging or degradation of the LED 13.

Within indoor matrix illumination there have been several approaches proposed to efficiently distribute power to a large number of discrete (LED) lighting sources. As the LED lighting sources operate at low voltages (typically around 3-5V), it is highly inefficient to firstly transform the (mains) power supply to the driving voltage and then distribute power to the devices at these low voltages. Preferably, power distribution is carried out at higher voltages and then locally transformed to the light source drive voltage. This reduces the power losses.

In order to solve the above problem in the present embodiment it is proposed to extend the basic electronic circuit of FIG. 9A to multiple distributed lighting sources (for instance LEDs), according to the circuit diagram of FIG. 9C comprising an array of the circuits of FIG. 9A. Each individual circuit comprises an LED 13 that is connected to a high voltage supply 10 via a switching power transistor 11 and an inductor. The voltage fed to the LED 13 is set by controlling the switching frequency or duty cycle of the power transistor 11.

In general, the LEDs 13 will be well separated from each other, e.g. being arranged in an array. According to prior art manufacturing technologies such a separated placement of the LEDs would require a large substrate area. In addition, a considerable substrate area would be required to create inductors with sufficient induction (as induction scales with the area of the spool). However, when fabricating such an array according to the inventive “cut-fold-extend” approach, the actual area of the substrate can be kept very low.

A possible layout of a fully integrated substrate for a distributed lighting system according to this invention for e.g. lighting applications is shown in FIG. 9D, depicting the circuit for one LED 13. In this layout the high voltage power supply 10 (realized as a conducting line) is connected to the switching power transistor 11 via a wide connecting line 15. The switching power transistor 11 is connected to the inductor 12, which in turn is connected to the LED 13. The switching power transistor 11 as well as the multi-winding inductor 12 are defined on the flexible substrate 1 in an extremely compact manner. By cutting along the dotted line 4″ and folding out the flexible substrate 1 along the lines 14, the LED 13 is separated from the high voltage power supply line 10 by a desired distance. Further an inductor 12 of sufficient value is created, whilst limiting the area of the flexible substrate 1 to a minimum.

In a still further integrated process, the LED 13 (in the form of a thin film OLED or a PLED) and the switching power transistor 11 (in the form of a thin film transistor) could be prepared directly onto the flexible substrate 1.

In this embodiment, the cost saving is in the integration of active and passive components and in the reduced area of flexible substrate required for separating the light sources and for creating the passive components, in this case the inductor.

It is apparent that as the proposed manufacturing process requires a flexible substrate, devices made using the cut-fold-extend approach will be intrinsically suitable for application in wearable technologies.

In another embodiment of the invention the “cut-fold-extend” technology is used to realize stacked electronics without needing multi-layered fabrication techniques. In this embodiment of “cut-fold-extend”-electronics it is proposed to increase the packing density of a low resolution electronics technology (i.e. printable/roll-to-roll electronics etc.) by fabricating electronics on a relatively large flexible substrate and then decreasing the footprint of the final device by cutting and folding the flexible substrate on top of itself. In this manner, a multi-layered system is created from only a single layer fabrication step.

In yet another embodiment of the invention the cutting and folding steps of the present invention are used to introduce a twisted structure into (pairs of) parallel running wires (interconnect) which connect the active or passive electric elements in the above explained integrated embodiments. By twisting or folding/unfolding the wires, it is possible to reduce the amount of EMI (electro-magnetic radiation) emitted by the interconnect wires, or, in for example a sensor application such as a microphone etc., reduce the amount of noise pick-up.

Generally, it is a goal of the invention to make most efficient use of the flexible substrate. In some of the above embodiments it has been proposed to create extendable electronic devices using the flexible properties of the flexible substrate by laying out the devices in a 2-dimensional pattern on the flexible substrate (e.g. FIG. 5A). This may result in an inefficient use of the flexible substrate as it is difficult to layout devices next to each other without introducing dead areas between devices. Therefore, layouts are preferred which are essentially in a simple rectangular form (e.g. FIGS. 7, 8, 9D); e.g. that have only one “wing” instead of two or four. This makes it easier to put them on a wafer or substrate in a regular X-Y pattern and increases the usage efficiency of the substrate.

Whilst the above embodiments of “cut-fold-extend” technology have been described in terms of LTPS technology, it may be possible to extend the invention to using flexible substrates based on amorphous-silicon (a-Si), nano-crystalline silicon, micro-crystalline silicon, hydrogenated amorphous silicon nitride, CdSe or polymer electronics technologies. In other embodiment, it will be possible to combine the concept of an extendable substrate, manufactured efficiently on a flexible substrate and then cut, folded and extended as described above and to combine this in the known manner with devices made of any of the known crystalline semiconductors (CMOS, BiPolar CMOS, GaAs, SiGe, silicon-on-insulator/silicon-on-anything etc.).

Further, in order to ensure that folding of the flexible substrate 1 does not result in fracture of the interconnects 8 or inductor lines, it is proposed to separate at the folding areas of the flexible substrate 1 the interconnect 8 into a plurality of split, parallel conducting lines 16, as shown in FIG. 10. Furthermore, whilst we have discussed embodiments in the form of flexible substrates, it is clear that the substrate need only show flexibility at the point where it is to be folded or deformed and as such may also comprise non-flexible areas.

1. A method for fabricating an electronic device or circuit, respectively, comprising providing a flexible substrate, defining onto the flexible substrate electric components and optionally interconnects, introducing breaks in the flexible substrate between the electric components and/or interconnects, and forming the flexible substrate into a deformed configuration by deforming parts of the flexible substrate as determined by the breaks.

2. The method for fabricating an electronic device or circuit as claimed in claim 1, wherein breaks are introduced by cutting and deformation is introduced by folding.

3. The method for fabricating an electronic device or circuit as claimed in claim 1, wherein portions of the substrate are removed, wherein preferably the removed portions have a rounded shape.

4. The method for fabricating an electronic device or circuit as claimed in claim 1, wherein the deformed configuration of the flexible substrate is attached to a carrier substrate.

5. The method for fabricating an electronic device or circuit as claimed in claim 2, wherein the deformed configuration of the flexible substrate is sandwiched between the carrier substrate and a cover substrate.

6. The method for fabricating an electronic device or circuit as claimed in claim 5, wherein the thickness and mechanical properties of the carrier substrate and the cover substrate are substantially the same.

7. The method for fabricating an electronic device or circuit as claimed in claim 1, wherein parts of the flexible substrate are deformed so that electronic components are extended.

8. The method for fabricating an electronic device or circuit as claimed in claim 1, wherein the flexible substrate is folded into a multi-layer configuration.

9. The method for fabricating an electronic device or circuit as claimed in claim 1, wherein parts of the flexible substrate containing interconnects are folded into a twisted configuration.

10. The method for fabricating an electronic device or circuit as claimed in claim 1, wherein at the deforming parts of the flexible substrate interconnects are defined as a plurality of split conducting lines.

11. The method for fabricating an electronic device or circuit as claimed in claim 1, wherein electric components comprise LTPS (Low Temperature Poly-Silicon) based electronic components.

12. The method for fabricating an electronic device or circuit as claimed in claim 1, wherein the electric components comprise electronic components selected from at least one of amorphous silicon based electronic components, nano-crystalline silicon based electronic components, micro-crystalline silicon based electronic components, hydrogenated a-Si nitride based electronic components, CdSe based electronic components, polymer based electronic components, or silicon-on-insulator/silicon-on-anything, CMOS, BiPolar CMOS, GaAs, SiGe based electronic components.

13. An electronic device or circuit, respectively, comprising a flexible substrate, onto which electric components and optionally interconnects are defined, wherein the flexible substrate has a deformed configuration, obtainable by a fabricating method as claimed in claim 1.

14. An electronic device or circuit, respectively, comprising a flexible substrate, onto which electric components and optionally interconnects are defined, wherein in the flexible substrate between the electric components and/or interconnects breaks are introduced, so that the flexible substrate is deformable or has a deformed configuration, respectively, as determined by the breaks.

15. The electronic device or circuit, respectively, as claimed in claim 13, wherein at least one central break is provided in the flexible substrate that does not extend to a peripheral edge of the flexible substrate.

16. The electronic device or circuit, respectively, as claimed in claim 15, wherein the at least one central break comprises multiple branches that are interconnected to each other.

17. The electronic device or circuit, respectively, as claimed in claim 13, wherein the electronic components and/or interconnects have a meandering structure, wherein between turns of the meandering structure breaks are provided.

18. The electronic device or circuit, respectively, as claimed in claim 17, wherein between turns of the meandering structure branches of a central break alternate with peripherals breaks that extend to peripheral edges of the flexible substrate.

19. The electronic device or circuit, respectively, as claimed in claim 13, wherein the flexible substrate in its non-deformed configuration has a rectangular shape.

20. The electronic device or circuit, respectively, as claimed in claim 13, wherein the deformed configuration of the flexible substrate is attached to a carrier substrate.

21. The electronic device or circuit, respectively, as claimed in claim 13, wherein the deformed configuration of the flexible substrate is sandwiched between the carrier substrate and a cover substrate, wherein preferably the thickness of the carrier substrate and the cover substrate are substantially the same.

22. The electronic device or circuit, respectively, as claimed in claim 13, wherein the flexible substrate comprises recesses formed by removing portions of the flexible substrate, wherein preferably the recesses have a rounded shape.

23. The electronic device or circuit, respectively, as claimed in claim 13, wherein at deformation parts of the flexible substrate interconnects are defined as a plurality of split conducting lines.
